(19) United States
(12) Patent Application Publication
(10) Pub. No.: US 2025/0194002 A1
(43) Pub. Date: Jun. 12, 2025

(54) VIBRATION SENSOR, ELECTRONIC DEVICE AND VIBRATION DETECTION METHOD

(71) Applicant: GOERTEK MICROELECTRONICS INC., Shandong (CN)

(72) Inventors: Tangliu Yan, Shandong (CN); Zhenwei Pei, Shandong (CN); Xunxun Bi, Shandong (CN); Luyu Duanmu, Shandong (CN)

(73) Assignee: GOERTEK MICROELECTRONICS INC., Shandong (CN)

(21) Appl. No.: 18/842,329

(22) PCT Filed: Feb. 28, 2023
(86) PCT No.: PCT/CN2023/078692

§ 371 Date: Aug. 28, 2024

(30) Foreign Application Priority Data
Feb. 28, 2022 (CN) 202210187465.7

(51) Int. Cl. H05K 1/02; B81B 3/00; G01H 11/06; H04R 19/04; H05K 1/18

(52) U.S. Cl. CPC H05K 1/0272; B81B 3/0078; G01H 11/06; H04R 19/04; H05K 1/183; B81B 2201/0257; B81B 2201/0285; B81B 2203/0127; B81B 2203/0315; B81B 2203/0353; H05K 2201/09018; H05K 2201/09072; H05K 2201/10083; H05K 2201/10151; H05K 2201/10522

(57) ABSTRACT

Disclosed are a vibration sensor, an electronic device and a vibration detection method. The vibration sensor comprises a circuit board assembly, a housing, a chip assembly, a vibration-pickup assembly and a through-hole. A back cavity is formed inside the circuit board assembly, the housing is mounted over the circuit board assembly, and the chip assembly is provided on a side of the circuit board assembly proximate to the housing and is electrically connected to the circuit board assembly. The vibration-pickup assembly is provided inside the cavity and dividing the cavity into a first cavity and a second cavity. The through-hole of the vibration sensor may be in communication with the back cavity and the second cavity.

### CROSS-REFERENCE TO RELATED APPLICATIONS

The present disclosure is a National Stage of Internation Application No. PCT/CN2023/078692 filed on Feb. 28, 2023, which claims priority to a Chinese patent application No. 202210187465.7 filed with the CNIPA on Feb. 28, 2022 and entitled “VIBRATION SENSOR AND ELECTRONIC DEVICE”, both of which are hereby incorporated by reference in their entireties.

### TECHNICAL FIELD

The present disclosure relates to a vibration sensor, an electronic device and a vibration detection method.

### BACKGROUND

In related art, a vibration sensor typically comprises a vibration-pickup unit and a microphone unit. The vibration-pickup unit is used for picking up bone vibrations from the environment and transmits them to the microphone unit, and the microphone unit is used for converting the vibration signals into electrical signals. To improve sensing performance, the microphone unit is usually provided with a hollow structure inside the circuit board to enlarge the space of the back cavity.

However, after providing the hollow structure inside the circuit board, it will increase the thickness of the circuit board, leading to an overall increase in the thickness of the vibration sensor; in addition, it will result in multiple bonding positions inside the circuit board to be exposed, which reduces product reliability, and also leads to complex structures of the vibration sensor, redundant manufacturing processes, and cost inefficiencies, thereby causing lower product yield.

### SUMMARY

An objective of embodiments of the present disclosure is to provide a new technical solution for a vibration sensor, an electronic device and a vibration detection method.

According to a first aspect of the embodiments of the present disclosure, a vibration sensor is provided, which comprises:
a circuit board assembly inside which a back cavity is formed;
a housing mounted over the circuit board assembly and provided with a first vent hole;
a chip assembly and a vibration-pickup assembly, the chip assembly being provided on a side of the circuit board assembly proximate to the housing and being electrically connected to the circuit board assembly, a cavity being formed between the chip assembly, the circuit board assembly, and the housing, and the vibration-pickup assembly being provided inside the cavity and dividing the cavity into a first cavity, which is proximate to the chip assembly, and a second cavity, which is proximate to the housing and is in communication with the first vent hole; and
a through-hole configured to be in communication with the back cavity and the second cavity.

Optionally, the circuit board assembly comprises a base plate and a looped sidewall connected on the periphery of the base plate:
the housing is mounted over the looped sidewall.

Optionally, the through-hole is provided on the looped sidewall.

Optionally, the vibration-pickup assembly comprises a diaphragm and a vibration loop, one end of the vibration loop is connected to the diaphragm, and the other end of the same is connected to the base plate; and
the through-hole is provided between the looped sidewall and the vibration loop.

Optionally, the vibration-pickup assembly is provided with a second vent hole, which is in communication with the first cavity and the second cavity.

Optionally, the vibration-pickup assembly separates the first cavity from the second cavity.

Optionally, the chip assembly is provided with an air hole, which is in communication with the first cavity and the back cavity.

Optionally, the circuit board assembly comprises a base plate over which the housing is mounted.

Optionally, there are provided a plurality of through-holes, with a cross-section thereof being at least one of square, circular, elliptical, and oval.

According to a second aspect of the embodiments of the present disclosure, a vibration sensor is provided, which comprises:
a circuit board assembly and a housing, the housing being mounted over the circuit board assembly and forming a cavity together with the circuit board assembly;
a chip assembly and a vibration-pickup assembly, the chip assembly being provided on a side of the circuit board assembly proximate to the housing and being electrically connected to the circuit board assembly, and the vibration-pickup assembly being provided inside the cavity and dividing the cavity into a first cavity, which is located on a side of the vibration-pickup assembly proximate to the chip assembly, and a second cavity, which is located on a side of the vibration-pickup assembly proximate to the housing;
a through-hole, the chip assembly comprising a MEMS chip, and the through-hole being configured to be in communication with a diaphragm of the MEMS chip and the second cavity.

According to a third aspect of the embodiments of the present disclosure, an electronic device is provided, which comprises the vibration sensor of the first aspect or the second aspect.

According to a fourth aspect of the embodiments of the present disclosure, a vibration detection method is provided, which is used for the above vibration sensor and comprises:

providing a chip assembly on a circuit board assembly and electrically connecting it to the circuit board assembly, the chip assembly comprising a MEMS chip:

providing a vibration-pickup assembly above the MEMS chip, a first cavity being formed between the vibration-pickup assembly, the circuit board assembly and the diaphragm of the MEMS chip:

providing a through-hole inside the circuit board assembly, and mounting the housing over the circuit board assembly, a second cavity being formed between the housing, the vibration-pickup assembly and the circuit board assembly, and the through-hole being capable of being in communication with the second cavity and a diaphragm of the MEMS chip so that a pressure difference between the first cavity and the second cavity can be conducted to two sides of the diaphragm of the MEMS chip.

A technical effect of the embodiments of the present disclosure is that:

The embodiments of the present disclosure provide a vibration sensor, which comprises a circuit board assembly, a housing, a chip assembly, a vibration-pickup assembly, and a through-hole. The through-hole of the vibration sensor may be in communication with the back cavity and the second cavity, that is, the through-hole may enlarge the space of the back cavity by means of the space of the second cavity, thus increasing the signal strength of the chip assembly, enhancing the signal output of the vibration sensor, improving the signal-to-noise ratio, signal acquisition capability and sensitivity of the devices in the vibration sensor, and optimizing the performance of the vibration sensor.

Other features and advantages of the present disclosure will be clarified from the following detailed description of exemplary embodiments of the disclosure with reference to the accompanying drawings.

### BRIEF DESCRIPTION OF THE DRAWINGS

The accompanying drawings incorporated in and constituting a part of the specification illustrate embodiments of present disclosure and together with the description thereof, serve to explain the principles of the disclosure.

FIG. 1 is a sectional view of a first type of vibration sensor according to an embodiment of the present disclosure:

FIG. 2 is a top view of the looped sidewall of a first type of vibration sensor according to an embodiment of the present disclosure:

FIG. 3 is a sectional view of a second type of vibration sensor according to an embodiment of the present disclosure:

FIG. 4 is a sectional view of a third type of vibration sensor according to an embodiment of the present disclosure:

FIG. 5 is a sectional view of a fourth type of vibration sensor according to an embodiment of the present disclosure.

### DESCRIPTION OF REFERENCE SIGNS

Wherein: 1, circuit board assembly; 11, back cavity; 12, base plate; 13, looped sidewall; 2, housing; 21, first vent hole; 3, chip assembly; 4, vibration-pickup assembly; 41, diaphragm; 42, vibration loop; 43, mass block; 44, second vent hole; 5, first cavity; 6, second cavity; 7, through-hole.

### DETAILED DESCRIPTION

Various exemplary embodiments of the present disclosure will now be described in detail with reference to the accompanying drawings. It is to be noted that unless otherwise specified, the scope of present disclosure is not limited to relative arrangements, numerical expressions and values of components and steps as illustrated in the embodiments.

Description to at least one exemplary embodiment is for illustrative purpose only, and in no way implies any restriction on the present disclosure or application or use thereof.

Techniques, methods and devices known to those skilled in the prior art may not be discussed in detail; however, such techniques, methods and devices shall be regarded as part of the description where appropriate.

In all the examples illustrated and discussed herein, any specific value shall be interpreted as illustrative rather than restrictive. Different values may be available for alternative examples of the exemplary embodiments.

It is to be noted that similar reference numbers and alphabetical letters represent similar items in the accompanying drawings. In the case that a certain item is identified in a drawing, further reference thereof may be omitted in the subsequent drawings.

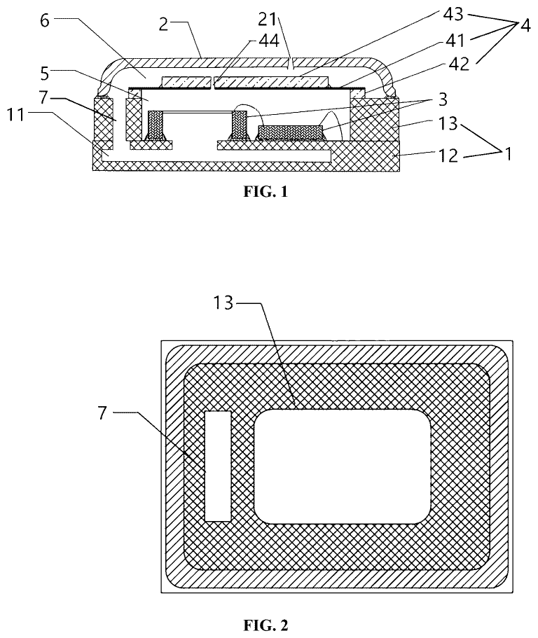

With reference to FIG. 1 to FIG. 5, the embodiment of the present disclosure provides a vibration sensor, and the vibration sensor may be used as a bone voiceprint vibration sensor to realize the pickup and transmission of bone vibration signals. The vibration sensor comprises:
a circuit board assembly 1, a housing 2, a chip assembly 3, a vibration-pickup assembly 4 and a through hole 7, the circuit board assembly 1 is formed with a back cavity 11 therein, and the back cavity 11 may provide a larger sound cavity for the chip assembly 3.

Referring to FIG. 1, the housing 2 is mounted over the circuit board assembly 1, and is provided with a first vent hole 21. The chip assembly 3 is provided on a side of the circuit board assembly 1 proximate to the housing 2 and is electrically connected to the circuit board assembly 1, such that signals processed by the chip assembly 3 may be smoothly transmitted to the circuit board assembly 1, thereby outputting the signals. The chip assembly 3, the circuit board assembly 1 and the housing 2 form a cavity between them, and the vibration-pickup assembly 4 is provided inside the cavity and divides the cavity into a first cavity 5 and a second cavity 6. The first cavity 5 is proximate to the chip assembly 3, and the second cavity 6 is proximate to the housing 2 and is in communication with the first vent hole 21.

The first cavity 5 may serve as a front acoustic chamber of the chip assembly 3, and the front acoustic chamber may be made relatively small to increase the sensitivity of the chip assembly 3. The back cavity 11 may serve as a part of a rear acoustic chamber of the chip assembly 3, and may be made relatively large to increase the signal strength of the chip assembly 3. The second cavity 6 may provide vibration space for the vibration-pickup assembly 4. To ensure effective vibration of the vibration-pickup assembly 4, the second cavity 6 has a relatively larger space. Referring to FIGS. 1 and 2, the through-hole 7 is configured to be in communication with the back cavity 11 and the second cavity 6, that is, the through-hole 7 may enlarge the space of the back cavity 11 by means of the space of the second cavity 6, thus increasing the signal strength of the chip assembly 3, enhancing the signal output of the vibration sensor, improving the signal-to-noise ratio, signal pickup capability and sensitivity of the devices in the vibration sensor, and optimizing the performance of the vibration sensor.

The operation principle of the vibration sensor is that external vibration and pressure signals are picked up by the vibration-pickup assembly 4, causing the vibration-pickup assembly 4 to vibrate. At this time, the vibration of the vibration-pickup assembly 4 causes air in the first cavity 5 to flow. For example, when the vibration-pickup assembly 4 receives a downward vibration signal, the diaphragm of the vibration-pickup assembly 4 moves downward, and the volume of the second cavity 6 in communication with the back cavity 11 increases, which is equivalent to further increasing the volume of the rear acoustic chamber of the chip assembly 3, thereby improving the output sensitivity of the vibration sensor. The chip assembly 3 may comprise vibration sensing chips such as MEMS chips and signal processing chips such as ASIC chips, the MEMS chip may detect the vibration signal of the airflow, convert it into an electrical signal, and then transmit the electrical signal to the electrical signal processing chip. The electrical signal processing chip performs operations such as signal amplification and conversion, and then outputs the signal by connecting it to the circuit board assembly 1 via a wire. After the back cavity 11 and the second cavity 6 are in communication with each other, the space of the back cavity 11 is enlarged, which may enhance the signal output of the vibration sensor, improve the signal-to-noise ratio, signal pickup capability and sensitivity of the devices in the vibration sensor, and optimize the performance of the vibration sensor.

The vibration sensor provided by the embodiments of the present disclosure comprises a circuit board assembly 1, a housing 2, a chip assembly 3, a vibration-pickup assembly 4, and a through-hole 7. A back cavity 11 is formed inside the circuit board assembly 1, and the housing 2 is mounted over the circuit board assembly 1 and is provided with a first vent hole 21. The chip assembly 3 is provided on a side of the circuit board assembly 1 proximate to the housing 2 and is electrically connected to the circuit board assembly 1. The vibration-pickup assembly 4 is provided inside the cavity and divides the cavity into a first cavity 5 and a second cavity 6. The through-hole 7 is configured to be in communication with the back cavity 11 and the second cavity 6, that is, the through-hole 7 may enlarge the space of the back cavity 11 by means of the space of the second cavity 6, thus increasing the signal strength of the chip assembly 3, enhancing the signal output of the vibration sensor, improving the signal-to-noise ratio, signal pickup capability and sensitivity of the devices in the vibration sensor, and optimizing the performance of the vibration sensor.

Additionally, when enlarging the space of the back cavity 11 by means of the space of the second cavity 6, the space of the back cavity 11 may be made relatively small. For example, when the back cavity 11 is made thin, it is also possible to reduce the thickness of the circuit board assembly 1, which lowers the overall height of the vibration sensor, and at the same time, also reduces the number of exposed bonding positions on the circuit board assembly 1, simplifies the installation process of the circuit board assembly 1, and ensures the stability and reliability of the overall structure of the circuit board assembly 1, thus simplifying the structure of the vibration sensor and reducing the difficulty and cost of manufacturing the vibration sensor.

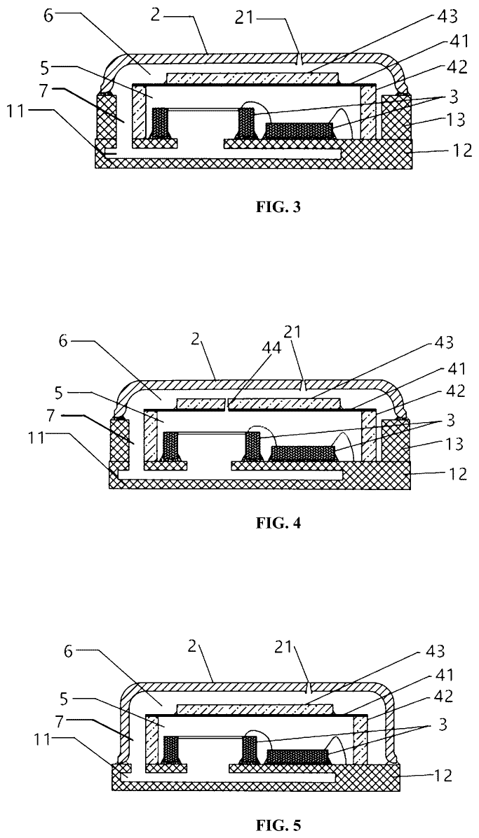

Optionally, referring to FIGS. 1 and 3, the circuit board assembly 1 comprises a base plate 12 and a looped sidewall 13 connected on the periphery of the base plate 12; the housing 2 is mounted over the looped sidewall 13.

Specifically, the base plate 12 may be provided with the back cavity 11 therein, and when the looped sidewall 13 is connected on the periphery of the base plate 12, it may not only effectively support the housing 2, but also form an accommodating space inside the circuit board assembly 1. When the housing 2 is mounted over the looped sidewall 13, sufficient space may be formed between the housing 2 and the circuit board assembly 1 to ensure that the chip assembly 3 and the vibration pickup assembly 4 are flexibly provided.

Optionally, referring to FIGS. 1 and 2, the through-hole 7 is provided on the looped sidewall 13.

Specifically, when the looped sidewall 13 effectively supports the housing 2, one end of the looped sidewall 13 may be proximate to the back cavity 11. For example, the lower end of the looped sidewall 13 in FIG. 1 is proximate to the back cavity 11. The other end of the looped sidewall 13 may be proximate to the second cavity 6. For example, the upper end of the looped sidewall 13 in FIG. 1 is proximate to the second cavity 6. When the through-hole 7 is provided on the looped sidewall 13, it specifically involves forming the through-hole 7 inside the looped sidewall 13, which facilitates communication between the back cavity 11 and the second cavity 6 while avoiding the need for a dedicated component to form the through-hole 7, simplifying the structure of the vibration sensor.

Optionally, referring to FIGS. 3 and 4, the vibration-pickup assembly 4 comprises a diaphragm 41 and a vibration loop 42, wherein one end of the vibration loop 42 is connected to the diaphragm 41, and the other end of the vibration loop 42 is connected to the base plate 12; and
the through-hole 7 is provided between the looped sidewall 13 and the vibration loop 42.

Specifically, during the operation of the vibration sensor, the vibration-pickup assembly 4 will vibrate frequently when it picks up external vibration signals and pressure signals, and specifically, the diaphragm 41 will vibrate toward its two sides. The vibration loop 42 may be specifically connected on the periphery of the diaphragm 41. On one hand, the vibration loop 42 may ensure the stability of the periphery of the diaphragm 41, and on the other hand, the vibration loop 42 may form a space inside it for the diaphragm 41 to vibrate, thereby increasing the vibration amplitude and sensitivity of the diaphragm 41. Additionally, a mass block 43 may further be provided on the diaphragm 41 to improve the stability of the diaphragm 41 on the premise of ensuring the flatness of the same.

Optionally, referring to FIGS. 1 and 4, the vibration-pickup assembly 4 is provided with a second vent hole 44, which is in communication with the first cavity 5 and the second cavity 6.

Specifically, when the vibration-pickup assembly 4 is provided inside the cavity and divides the cavity into the first cavity 5 and the second cavity 6, since the first cavity 5 is proximate to the chip assembly 3, that is, the first cavity 5 is formed between the vibration-pickup assembly 4 and the chip assembly 3, to prevent the first cavity 5 from being too enclosed and thus hindering the vibration of the vibration-pickup assembly 4 and the chip assembly 3, the first cavity 5 may be in communication with the second cavity 6 via the second vent hole 44 in the vibration-pickup assembly 4. Since the second cavity 6 may be in communication with the outside environment through the first vent hole 21, the ventilation of the first cavity 5 and the second cavity 6 is ensured, allowing the vibration-pickup assembly 4 and the chip assembly 3 to vibrate flexibly.

Optionally, referring to FIGS. 3 and 5, the vibration-pickup assembly 4 separates the first cavity 5 from the second cavity 6.

Specifically, the vibration-pickup assembly 4 separating the first cavity 5 from the second cavity 6 means that no micrometer-level vent hole is provided in the vibration-pickup assembly 4; instead, the first cavity 5 and the second cavity 6 are separated by the entire vibration-pickup assembly 4. This simplifies the manufacturing process and material complexity of the vibration-pickup assembly 4, saving the manufacturing costs of the vibration-pickup assembly 4. The first cavity 5 may vent through the membrane structure on the chip assembly 3. For example, the chip assembly 3 may comprise a vibration sensing chip such as a MEMS chip, and the vibration sensing chip comprises a membrane structure formed with micro air holes, which may likewise ensure the air permeability of the first cavity 5 and the second cavity 6.

Optionally, the chip assembly 3 is provided with an air hole, which is in communication with the first cavity 5 and the back cavity 11.

Specifically, the chip assembly 3 may comprise a vibration sensing chip such as a MEMS chip and an electrical signal processing chip such as an ASIC chip, and may be sequentially electrically connected to the vibration sensing chip, the electrical signal processing chip, and the circuit board assembly 1 by means of gold wires. The vibration sensing chip may comprise a membrane structure formed with micro air holes. With the multiple micro-air holes provided on the membrane structure of the vibration sensing chip, it is possible to ensure the communication between the first cavity 5 and the back cavity 11, allowing the first cavity 5 and the back cavity 11 to vent through the first vent hole 21 together.

Optionally, referring to FIG. 5, the circuit board assembly 1 comprises a base plate 12, and the housing 2 is mounted over the base plate 12.

Specifically, the housing 2 may be an inverted lid-like structure, and the edge of the housing 2 may be bonded on the periphery of the base plate 12, such that sufficient accommodation space is formed between the housing 2 and the circuit board assembly 1, so as to provide the chip assembly 3 and the vibration-pickup assembly 4. To ensure the structural strength of the vibration sensor, the housing 2 may be a metal housing, which may function to protect and isolate from interference, and when both the chip assembly 3 and the vibration-pickup assembly 4 are covered by the metal housing, it is possible to ensure the stability of signal processing and transmission of the chip assembly 3.

Optionally, referring to FIG. 2, there are provided a plurality of the through-holes 7, with the cross-sectional shape thereof being at least one of square, circular, elliptical, and oval.

Specifically, when the through-hole 7 is provided in the looped sidewall 13, the number of through-hole 7 in the looped sidewall 13 may be one, two, three, four, or more, which is specifically depended on the size of the cross-section of the through-hole 7 and the requirements for communication between the back cavity 11 and the second cavity 6. The cross-sectional shape of the through-hole 7 may be square, such as the rectangle shown in FIG. 2, or it may be at least one of circular, elliptical, and oval shapes. For example, when there are multiple through-holes 7, their cross-sectional shapes may be different so as to increase the flexibility of providing the through-holes 7.

The embodiments of the present disclosure also provides another vibration sensor, comprising:
a circuit board assembly 1 and a housing 2, the housing 2 being mounted over the circuit board assembly 1 and forming a cavity together with the circuit board assembly 1;
a chip assembly 3 and a vibration-pickup assembly 4, the chip assembly 3 being provided on a side of the circuit board assembly 1 proximate to the housing 2 and being electrically connected to the circuit board assembly 1, and the vibration-pickup assembly 4 being provided inside the cavity and dividing the cavity into a first cavity 5, which is located on a side of the vibration-pickup assembly 4 proximate to the chip assembly 3, and a second cavity 6, which is located on a side of the vibration-pickup assembly 4 proximate to the housing 2; and
a through-hole 7, the chip assembly 3 comprising a MEMS chip, and the through-hole 7 being configured to be in communication with a diaphragm of the MEMS chip and the second cavity 6.

Wherein, by configuring the through-hole 7 to be in communication with the diaphragm of the MEMS chip (that is, the back cavity 11) and the second cavity 6, the through-hole 7 may enlarge the space of the back cavity 11 of the MEMS chip by means of the space of the second cavity 6, thus increasing the signal strength of the chip assembly 3, enhancing the signal output of the vibration sensor, improving the signal-to-noise ratio, signal pickup capability and sensitivity of the devices in the vibration sensor, and optimizing the performance of the vibration sensor.

The embodiments of the present disclosure also provide an electronic device, which comprises the aforementioned vibration sensor.

Specifically, the vibration sensor of the electronic device comprises a circuit board assembly 1, a housing 2, a chip assembly 3, a vibration-pickup assembly 4, and a through-hole 7. The circuit board assembly 1 is formed with a back cavity 11 therein, and the housing 2 is mounted over the circuit board assembly 1 and is provided with a first vent hole 21 therein. The chip assembly 3 is provided on a side of the circuit board assembly 1 proximate to the housing 2 and is electrically connected to the circuit board assembly 1. The vibration-pickup assembly 4 is provided inside the cavity and divides the cavity into a first cavity 5 and a second cavity 6. The through-hole 7 may be in communication with the back cavity 11 and the second cavity 6, that is, the through-hole 7 may enlarge the space of the back cavity 11 by means of the space of second cavity 6, thus increasing the signal strength of the chip assembly 3, enhancing the signal output of the vibration sensor, improving the signal-to-noise ratio, signal pickup capability and sensitivity of the devices in the vibration sensor, and optimizing the sensing performance of the electronic device.

Optionally, the electronic device may comprise, but is not limited to, microphones, headphones, smartwatches, mobile phones, tablets, e-readers, MP3 players, MP4 players, computers, set-top boxes, smart TVs, and wearable devices.

The embodiments of the present disclosure also provide a vibration detection method, which may be used in the vibration sensor, and comprise:
providing a chip assembly 3 on a circuit board assembly 1 and electrically connecting it to the circuit board assembly 1, the chip assembly 3 comprising a MEMS chip;
providing a vibration-pickup assembly 4 above the MEMS chip, a first cavity 5 being formed between the vibration-pickup assembly 4, the circuit board assembly 1 and the diaphragm of the MEMS chip;
providing a through-hole 7 inside the circuit board assembly 1, and mounting
the housing 2 over the circuit board assembly 1, a second cavity 6 being formed between the housing 2, the vibration-pickup assembly 4 and the circuit board assembly 1, and the through-hole 7 being capable of being in communication with the second cavity 6 and a diaphragm of the MEMS chip so that a pressure difference between the first cavity 5 and the second cavity 6 can be conducted to two sides of the diaphragm of the MEMS chip. This allows the MEMS chip to detect the vibration signal of the airflow, convert it into the electrical signal, and then transmit the electrical signal to the electrical signal processing chip. The electrical signal processing chip completes operations such as signal amplification and conversion, and then outputs the electrical signal by connecting it to the circuit board assembly 1 with the wire.

Wherein, the first cavity 5 may serve as a front acoustic chamber of the chip assembly 3, and the front acoustic chamber may be made relatively small to increase the sensitivity of the chip assembly 3. The second cavity 6 may provide vibration space for the vibration-pickup assembly 4. To ensure effective vibration of the vibration-pickup assembly 4, the second cavity 6 has a relatively larger space. Referring to FIGS. 1 and 2, the through-hole 7 is configured to be in communication with the diaphragm of the MEMS chip (that is, the back cavity 11) and the second cavity 6, that is, the through-hole 7 may enlarge the space of the back cavity 11 by means of the space of the second cavity 6, thus increasing the signal strength of the MEMS chip, enhancing the signal output of the vibration sensor, improving the signal-to-noise ratio, signal pickup capability and sensitivity of the devices in the vibration sensor, and optimizing the performance of the vibration sensor.

Although some specific embodiments of the present disclosure have been described in detail by way of examples, it should be understood by those skilled in the art that the above examples are for illustrative purposes only and are not intended to limit the scope of the present disclosure. Those skilled in the art should understand that the above embodiments may be modified without departing from the scope and spirit of the present disclosure. The scope of the present disclosure is limited by the appended claims.

1. A vibration sensor, comprising:
a circuit board assembly, inside which a back cavity is formed;
a housing mounted over the circuit board assembly and provided with a first vent hole;
a chip assembly provided on a side of the circuit board assembly proximate to the housing and electrically connected to the circuit board assembly,
wherein a cavity is formed between the chip assembly, the circuit board assembly, and the housing;
a vibration-pickup assembly provided inside the cavity and dividing the cavity into a first cavity, proximate to the chip assembly, and a second cavity, proximate to the housing and in communication with the first vent hole; and
a through-hole configured for communication with the back cavity and the second cavity.

2. The vibration sensor of claim 1, wherein the circuit board assembly comprises a base plate and a looped sidewall connected on a periphery of the base plate; and
the housing is mounted over the looped sidewall.

3. The vibration sensor of claim 2, wherein the through-hole is provided on the looped sidewall.

4. The vibration sensor of claim 2, wherein the vibration-pickup assembly comprises a diaphragm and a vibration loop, a first end of the vibration loop is connected to the diaphragm, and a second end of the vibration loop is connected to the base plate; and
the through-hole is provided between the looped sidewall and the vibration loop.

5. The vibration sensor of claim 1, wherein the vibration-pickup assembly is provided with a second vent hole, in communication with the first cavity and the second cavity.

6. The vibration sensor of claim 1, wherein the vibration-pickup assembly separates the first cavity from the second cavity.

7. The vibration sensor of claim 1, wherein the chip assembly is provided with an air hole, in communication with the first cavity and the back cavity.

8. The vibration sensor of claim 1, wherein the circuit board assembly comprises a base plate over which the housing is mounted.

9. The vibration sensor of claim 1, further comprising a plurality of through-holes, wherein each through-hole has a cross-section being at least one of square, circular, elliptical, and oval.

10. A vibration sensor, comprising:
a circuit board assembly and a housing, the housing being mounted over the circuit board assembly and forming a cavity together with the circuit board assembly;
a chip assembly provided on a side of the circuit board assembly proximate to the housing and electrically connected to the circuit board assembly,
wherein the chip assembly comprises a MEMS chip;
a vibration-pickup assembly provided inside the cavity and dividing the cavity into a first cavity, located on a side of the vibration-pickup assembly proximate to the chip assembly, and a second cavity, which is located on a side of the vibration-pickup assembly proximate to the housing; and
a through-hole, the through-hole configured to be in communication with a diaphragm of the MEMS chip and the second cavity.

11. An electronic device, comprising the vibration sensor of claim 1.

12. A vibration detection method using the vibration sensor of claim 1, comprising:
providing a chip assembly on a circuit board assembly and electrically connecting it to the circuit board assembly, the chip assembly comprising a MEMS chip;
providing a vibration-pickup assembly above the MEMS chip, a first cavity being-formed between the vibration-pickup assembly, the circuit board assembly and the diaphragm of the MEMS chip;
providing a through-hole inside the circuit board assembly; and
mounting the housing over the circuit board assembly,
a second cavity formed between the housing, the vibration-pickup assembly and the circuit board assembly, and
the through-hole configured for communication with the second cavity and a diaphragm of the MEMS chip so that a pressure difference between the first cavity and the second cavity is conducted to two sides of the diaphragm of the MEMS chip.
